(19) United States
(12) Patent Application Publication
(10) Pub. No.: US 2025/0208196 A1
(43) Pub. Date: Jun. 26, 2025

(54) METHODS AND APPARATUS TO DETECT CAPACITOR LEAKAGE IN SEMICONDUCTOR DIES

(71) Applicant: Intel Corporation, Santa Clara, CA (US)

(72) Inventors: Vinayak Agrawal, Bengaluru (IN); Syed Thameem Syed Ansari, Bengaluru (IN); Mohamed Mohideen Hassaly Abdul Rahuman, Bengaluru (IN); Dwaipayan Sil, Portland, OR (US); Syed Roomi Naqvi, Tempe, AZ (US); Mirza Mehedi Jahan, Gilbert, AZ (US)

(21) Appl. No.: 18/394,740

(22) Filed: Dec. 22, 2023

(51) Int. Cl. G01R 31/28; G01R 31/52

(52) U.S. Cl. CPC G01R 31/2851; G01R 31/52

(57) ABSTRACT

Systems, apparatus, articles of manufacture, and methods are disclosed to detect capacitor leakage in semiconductor dies. An example apparatus includes a semiconductor die comprising a transistor, a first contact on a first surface of the semiconductor die, the first contact electrically coupled to a first terminal of the transistor, a second contact on the first surface of the semiconductor die, the second contact electrically coupled to a second terminal of the transistor, a capacitor between the first surface and a second surface of the semiconductor die opposite the first surface, the second contact electrically coupled to a first electrode of the capacitor, and a third contact on the first surface of the semiconductor die, the third contact electrically coupled to a second electrode of the capacitor.

### FIELD OF THE DISCLOSURE

This disclosure relates generally to semiconductor dies and, more particularly, to methods and apparatus to detect capacitor leakage in semiconductor dies.

### BACKGROUND

Integrated circuit (IC) chips and/or semiconductor dies are routinely connected to larger circuit boards such as motherboards and other types of printed circuit boards (PCBs) via a package substrate. IC chips and/or dies have exhibited reductions in size and increases in interconnect densities as technology has advanced.

### BRIEF DESCRIPTION OF THE DRAWINGS

FIG. 1 illustrates an example integrated circuit (IC) package on a printed circuit board (PCB).

FIG. 2A is a cross-sectional view of an example semiconductor die included in the example IC package of FIG. 1.

FIG. 2B is a plan view of the example semiconductor die included in the example IC package of FIGS. 1 and 2A.

FIG. 3 is an example IC package constructed in accordance with teachings disclosed herein.

FIG. 4 is a flowchart representative of an example method to detect defects associated with the example semiconductor die of FIGS. 1, 2A, 2B, and 3.

FIG. 5 illustrates an example test probe to determine defects associated with the example semiconductor die of FIGS. 1, 2A, 2B and/or 3.

FIG. 6 is a top view of a wafer including dies that may be included in an IC package constructed in accordance with teachings disclosed herein.

FIG. 7 is a cross-sectional side view of an IC device that may be included in an IC package constructed in accordance with teachings disclosed herein.

FIG. 8 is a cross-sectional side view of an IC device assembly that may include an IC package constructed in accordance with teachings disclosed herein.

FIG. 9 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

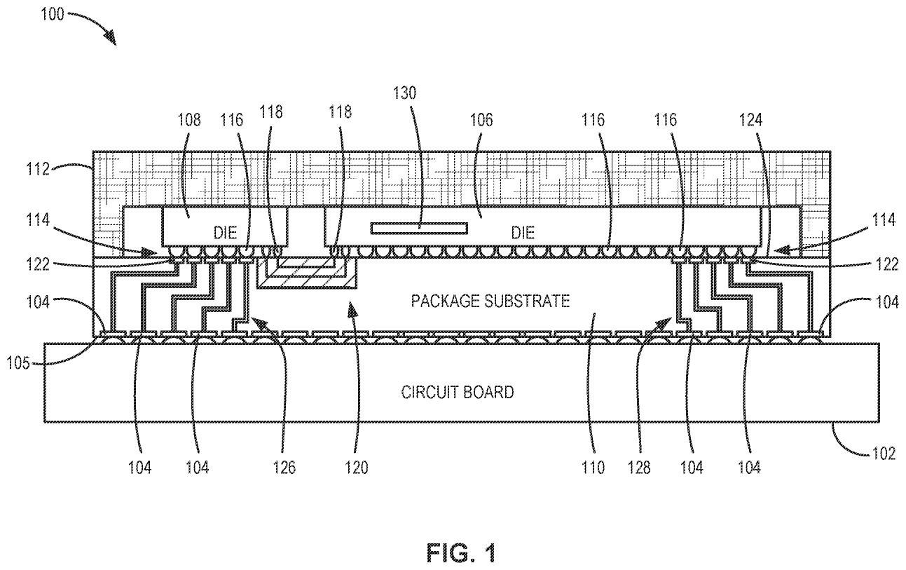

FIG. 1 illustrates an example IC package (e.g., a semiconductor package) 100 constructed in accordance with teachings disclosed herein. In the illustrated example, the IC package 100 is electrically coupled to an example circuit board 102 via an array of example contact pads or lands 104 on an example mounting surface (e.g., a bottom surface) 105 of the package. In some examples, the IC package 100 may include balls, pins, and/or pads, in addition to or instead of the contact pads 104, to enable the electrical coupling of the package 100 to the circuit board 102. In this example, the package 100 includes two example semiconductor (e.g., silicon) dies 106, 108 (sometimes also referred to as chips or chiplets) that are mounted to an example package substrate 110 and enclosed by an example package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is electrically and mechanically coupled to the substrate 110 via corresponding arrays of example interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, example core bumps 116 and example bridge bumps 118. As used herein, core bumps are bumps on dies through which electrical signals pass between the dies and other components either within an IC package containing the dies (e.g., a different die) or external to the IC package. Alternatively, as used herein, bridge bumps are bumps on the dies through which electrical signals pass between different ones of the dies within an IC package. More particularly, bridge bumps differ from core bumps in that bridge bumps electrically connect two or more different dies via an interconnect bridge (e.g., example interconnect bridge 120 of FIG. 1) embedded in an underlying substrate (e.g., the package substrate 110). As represented in FIG. 1, the example core bumps 116 are typically larger than bridge bumps 118. In some examples, the interconnect bridge 120 and the associated bridge bumps 118 are omitted.

As shown in the illustrated example, when the dies 106, 108 are mounted to the package substrate 110, the core bumps 116 are physically connected and electrically coupled to contact pads 122 on an example inner surface 124 of the substrate 110. The contact pads 122 on the inner surface 124 of the package substrate 110 are electrically coupled to the landing pads 104 on the bottom (external) surface 105 of the substrate 110 (e.g., a surface opposite the inner surface 124) via example internal interconnects 126, 128 within the substrate 110.

Semiconductor packages often employ transmission lines, such as traces, microstrips, and/or other electrical routing, to transmit signals and/or power between package components. In the example of FIG. 1, there is a complete signal path between the bumps 116 of the dies 106, 108 and the landing pads 104 mounted to the circuit board 102 that pass through the contact pads 122 and the interconnects 126, 128 provided therebetween. As electronic systems become more complex and electrical interfaces in the electronic systems operate at higher frequencies, dense signal processing areas can cause significant crosstalk between adjacent signal paths in such densely packed spaces. Such crosstalk can reduce the performance of the package. Capacitors may be implemented to increase the power efficiency of such packages. For example, capacitors may be implemented in high speed input/output (HSIO) interfaces, die to die (D2D) interfaces, high bandwidth memory (HBM) interfaces, graphical processing units (GPUs), central processing units (CPUs), etc.

Capacitors may be implemented in semiconductor dies to increase the power efficiency of the dies and the associated IC package(s) containing such dies. In FIG. 1, the example die 106 includes an example capacitor 130 to increase the power efficiency of the IC package 100. For example, the capacitor 130 can absorb voltage fluctuations associated with the die 106. As such, the example capacitor 130 may release any energy it may have absorbed back to the die 106 during operation, enabling the die 106 to maintain voltage levels with less power consumption while in operation. In some examples, both of the dies 106, 108 may include multiple ones of the capacitor 130. In some examples, the capacitor 130 is a thin film metal-insulator-metal (MIM) capacitor.

Some previous approaches to implement capacitors with semiconductor dies include usage of deep trench capacitors (DTCs) disposed in silicon interposers. However, these DTCs are expensive to fabricate in the silicon interposers. Further, the silicon interposers have size limitations and are typically distinct from the semiconductor dies. Other previous implementations dispose integrated passive devices (IPDs), rather than a full silicon interposer, in epoxy molding of an example IC package. However, these implementations may not be able to detect defective capacitors during assembly and/or operation. For logic circuits and capacitors that are connected in parallel (e.g., between the power supply voltage (Vdd) and ground (GND)), conventional testing methods (e.g., wafer sorting, class testing, thermal imaging, infrared (IR) spectroscopy, automatic test equipment (ATE) testing, etc.) may only detect leakage of the logic circuit (e.g., transistor leakage), instead of capacitor leakage exclusively (e.g., independent of transistor leakage). As a result, an example semiconductor die (e.g., the die 106) may include a defective capacitor but still inadvertently pass such conventional testing methods. Specifically, capacitor leakage may go undetected with conventional testing methods because capacitor leakage is typically much smaller (e.g. orders of magnitude smaller) than transistor leakage and, therefore, may provide a negligible (e.g., minor, undetectable, etc.) contribution to the overall leakage of an associated circuit. In some examples, the testing methods disclosed herein to separately measure or detect transistor leakage and capacitor leakage may be performed prior to singulation (e.g., dicing) of the dies and/or at any time prior to assembly/packaging.

Capacitor leakage, or any other defect associated with a capacitor, may risk the functionality of an example IC package by causing voltage leakage, ground leakage, overloading of the power supply (e.g., the power management integrated circuit (PMIC)), etc. Such defects may degrade the performance of IC packages over time, and can cause defective performance in the field. Some example industries (e.g., automotive, communications, medicine, etc.) may have reliability metrics (e.g., defective parts per million (DPM)) that underscore avoiding and/or detecting defective capacitors in IC packages. Simply avoiding the use of capacitors in semiconductor dies altogether may prevent the detrimental effects of capacitor leakage, but, as previously mentioned, the inclusion of capacitors in semiconductor dies provide performance benefits to such semiconductor dies and the associated IC packages.

Examples disclosed herein enable the usage of capacitors included in semiconductor dies. For example, disclosed examples provide effective detection methods to identify defective capacitors in an example semiconductor die (e.g., the die 106). Examples disclosed herein distinguish between transistor leakage (associated with leakage across the terminals of one or more transistors) and capacitor leakage (associated with leakage across the electrodes of a capacitor). For example, disclosed examples define a first current path to measure transistor leakage and a second current path to measure capacitor leakage. Disclosed examples separate the first and second current paths so that current can pass through the capacitor exclusively (e.g., independent of associated transistors in an associated logic circuit). This is accomplished by electrically isolating the voltage supply for the first and second current paths within the semiconductor die through the use of separate bumps or contacts on the die for each of the capacitor and the logic circuit. In some such examples, the capacitor may still be connected in parallel with the associated logic circuit through a package substrate to which the semiconductor die is mounted. That is, while the capacitor and logic circuit are associated with electrically isolated bumps on the die, the voltage supply bump for the capacitor and the voltage supply bump for the logic circuit are still connected (e.g., shorted) through the package substrate (externally to the semiconductor die).

In some disclosed examples, measuring capacitor leakage by supplying a voltage to the example semiconductor die can also identify capacitor defects associated with changes in temperature (since voltage varies as temperature varies). In some disclosed examples, measurements across the first current path and/or the second current path may be obtained with any suitable wafer sorting test methods, wafer-level-burn-in techniques, etc., during assembly of the example semiconductor die. Therefore, disclosed examples may detect capacitor leakage prior to fabricating the IC package and/or prior to sending the assembled IC package into the field. Additionally, disclosed examples may detect capacitor leakage in IC packages that have been returned from the field. While conventional testing methods may yield 500 or more DPM, examples disclosed herein may provide for an improved DPM (e.g., in a range from 40-50 DPM).

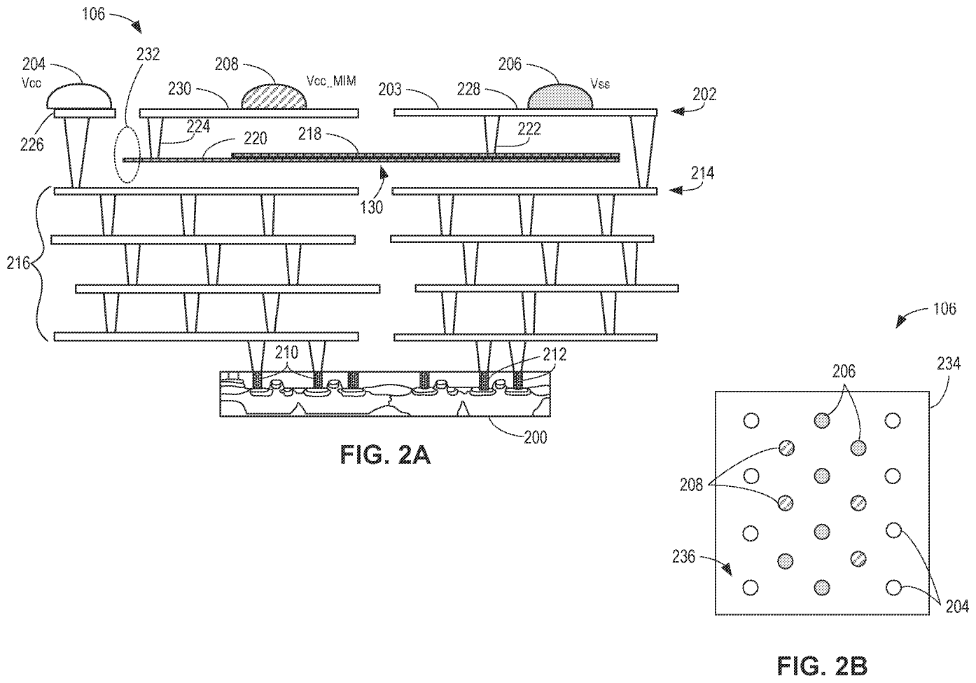

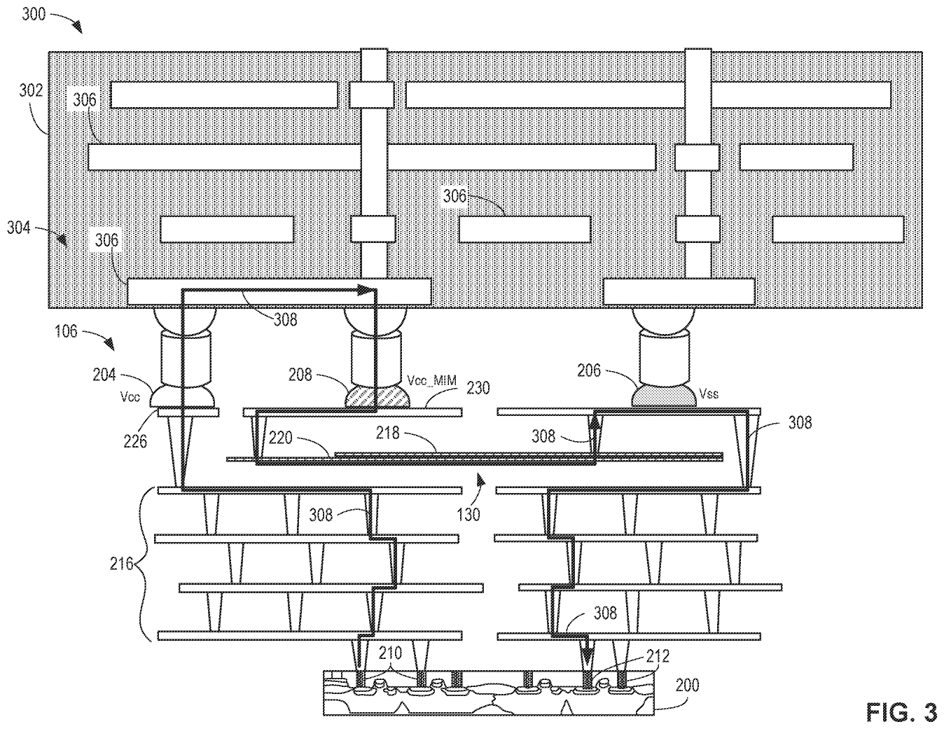

FIG. 2A is a cross-sectional view of the example semiconductor die 106 constructed in accordance with disclosed examples. For purposes of simplicity, in the illustrated example of FIG. 2A, metal layers (and interconnecting vias) in the semiconductor die 106 are shown without associated dielectric material between the metal layers. The example semiconductor die 106 includes one or more example transistor(s) 200, the example capacitor 130, and a first metal layer 202 having a first example surface 203 on which is disposed a first example contact (e.g., bump) 204, a second example contact 206, and a third example contact 208. In some examples, the first, second, and third contacts 204, 206, 208 correspond to ones of the core bumps 116 and/or the bridge bumps 118 of the first die 106 shown in FIG. 1. Thus, the semiconductor die 106 has an inverted orientation in FIG. 2 relative to the orientation shown in FIG. 1. In this example, the third example contact 208 is positioned between and spaced apart from the first and second contacts 204, 206. As such, the third example contact 208 is closer to the second contact 206 than the first contact 204 is to the second contact 206. In some examples, the first, second, and third contacts 204, 206, 208 are couplable with an example package substrate (e.g., the package substrate 110 of FIG. 1 and as discussed in further detail below in connection with FIG. 3). The first example contact 204 is electrically coupled to a first example terminal 210 (e.g., drain, drain terminal, etc.) of one or more of the transistor(s) 200. Further, the second example contact 206 is electrically coupled to a second example terminal 212 (e.g., source, source terminal, etc.) of the transistor(s) 200. In this example, the transistor(s) 200 implement an example inverter. However, the transistor(s) 200 may be constructed and interconnected to implement any other type of electrical circuit.

In FIG. 2A, different ones of the first, second, and third example contacts 204, 206, 208 are positioned on different portions (e.g., segments) of the first metal layer 202. Specifically, in this example, the first metal layer 202 includes a first example metal portion 226, a second example metal portion 228, and a third example metal portion 230. The first example contact 204 is associated with (e.g., disposed on, connected to, in contact with, etc.) the first metal portion 226, the second contact 206 is associated with (e.g., disposed on, connected to, in contact with, etc.) the second metal portion 228, and the third contact 208 is associated with (e.g., disposed on, connected to, in contact with, etc.) the third metal portion 230. The first example metal portion 226 is spaced apart (e.g., electrically isolated) from the second metal portion 228. Additionally, the first example metal portion 226 is spaced apart (e.g., electrically isolated) from the third metal portion 230. Put differently, the first, second, and third metal portions 226, 228, 230 are spaced apart (e.g., electrically isolated) from one another.

The example capacitor 130 is positioned between the first metal layer 202 and a second example metal layer 214 of the die 106. The second example metal layer 214 is one of example intermediary metal layers 216 that are positioned between the first metal layer 202 and the transistor(s) 200. The example capacitor 130 includes a first example electrode 218 electrically coupled to the second contact 206 and a second example electrode 220 electrically coupled to the third contact 208. In particular, the first example electrode 218 and the second contact 206 are electrically coupled through an example via 222 extending from the first electrode 218 to the first metal layer 202. Further, the second example electrode 220 and the third contact 208 are electrically coupled through an example via 224 extending from the second electrode 220 to the first metal layer 202. Thus, the example capacitor 130 capacitively couples the third contact 208 to the second contact 206. As shown in FIG. 2A, the second example electrode 220 is closer to the transistor(s) 200 than the first electrode 218 is to the transistor(s) 200. In other examples, the relative positioning of the electrodes 218, 220 may be reversed with the first example electrode 218 closer to the transistor(s) 200 than the second electrode 220 is to the transistor(s) 200.

The first example electrode 218 and the second electrode 220 extend in axes (e.g., planes) substantially parallel (e.g., parallel within 10 degrees) to the first metal layer 202. For example, the second electrode 220 extends a first length along a first example axis (e.g., a direction extending horizontally left and right from the perspective shown in FIG. 2A). Additionally, in this example, the third example metal portion 230 extends a second length along the first axis less than the first length. As shown in FIG. 2A, the second electrode 220 extends beyond both ends of the second length of the third metal portion 230 along the first axis. Thus, an example portion of the second electrode 220 may extend into a space 232 (e.g., area, position, opening, etc.) between the first and third metal portions 226, 230 in a direction substantially perpendicular (e.g., perpendicular within 10 degrees) to the first metal layer 202 (e.g., substantially perpendicular to the first axis). Further, both the second and third example metal portions 228, 230 overlap with the first and second electrodes 218, 220 in a direction substantially perpendicular to the first metal layer 202 (e.g., substantially perpendicular to the first axis).

FIG. 2B is a plan view of the example semiconductor die 106 facing towards the surface containing the bumps 204, 206, 208 (e.g., looking down on the semiconductor die 106 from above in the orientation shown in FIG. 2A). In the illustrated example of FIG. 2B, the bumps 204, 206, 208 are surrounded by a solder resist layer 234 that is deposited over the first metal layer 202. The solder resist layer 234 defines an exterior surface 236 of the semiconductor die 106. For this reason, the different portions 226, 228, 230 of the first metal layer 202 are not shown in FIG. 2B. As shown in FIG. 2B, the example semiconductor die 106 includes a set of multiple ones of the first contact 204, a set of multiple ones of the second contact 206, and a set of multiple ones of the third contact 208. Each of the example sets of multiple first, second, and third contacts 204, 206, 208 are distributed across the exterior surface 236 of the semiconductor die 106 (and across the underlying surface of the first metal layer 202). Further, in some examples, different ones of the third contacts 208 are electrically coupled to the second electrode 220 of the capacitor 130 (FIG. 2A). In some such examples, the third contacts 208 are electrically coupled to the same portion 230 of the first metal layer 202. In other such examples, different ones of the third contacts 208 are coupled to separate discrete portions of the first metal layer 202 that are independently coupled (through separate vias) to the second electrode 220. In other examples, different ones of the third contacts 208 may be electrically coupled to different example capacitors (e.g., different second electrodes of example capacitors). In the same manner, different ones of the second contacts 206 may be electrically coupled to the first electrode 218 or to different first electrodes of different capacitors and/or coupled to the same portion 228 of the first metal layer 202 or coupled to separate discrete portions of the first metal layer 202. Additionally, different ones of the example sets of multiple first and second contacts 204, 206 may be coupled to the same transistor(s) (e.g., the transistor(s) 200) and/or different transistor(s). In some examples, the multiple first, second, and third contacts 204, 206, 208 may be spaced approximately 110 micrometers (μm) apart from one another.

FIG. 3 is an example IC package 300 constructed in accordance with teachings disclosed herein. The example IC package 300 includes an example package substrate 302 coupled to the semiconductor die 106 of FIGS. 2A and 2B. The example package substrate 302 includes an example dielectric 304 and example conductive layers 306. In some examples, the package substrate 110 of FIG. 1 may be implemented as the package substrate 302. As such, the example first, second, and third example contacts 204, 206, 208 may represent the bumps 116 and/or the bumps 118 of FIG. 1. Thus, similar to what was noted above in connection with FIG. 2A, the orientation of the die 106 and the package substrate 302 in FIG. 3 is inverted compared to the orientation of the die 106 and the package substrate 110 in FIG. 1.

In the illustrated example, the first, second, and third example contacts 204, 206, 208 are electrically coupled to corresponding contacts on the package substrate 302. As a result, the example package substrate 302 is electrically coupled to the second electrode 220 via the third contact 208. Further, the example package substrate 302 is electrically coupled to the first electrode 218 via the second contact 206. As discussed above, within the example die 106, the first contact 204 (e.g., and the first portion 226 of the first metal layer 202) is electrically isolated from the third contact 208 (e.g., and the third portion 230 of the first metal layer 202). However, in the example of FIG. 3, the first contact 204 is electrically coupled to the third contact 208 through the package substrate 302. In some examples, as shown, the first and third contacts 204, 208 are electrically coupled (e.g., shorted) through the conductive layer 306 closest to the die 106 to reduce the distance the current travels between the contacts 204, 208. In this manner, the first, second, and third contacts 204, 206, 208 (when connected through the package substrate 302) create a complete circuit in which the logic circuit (e.g., the transistor(s) 200) are connected in parallel with the capacitor 130. That is, as shown in the illustrated example, current may flow sequentially from the first example terminal 210 of the transistor(s) 200, through the metal layers 216 to the first contact 204, to one of the conductive layers 306 in the package substrate 302, to the third contact 208, to the second electrode 220 of the capacitor 130 so as to capacitively couple with the first electrode 218 of the capacitor 130. Further, as shown in FIG. 3, the first electrode 218 is electrically coupled to the second contact 206, and which is electrically coupled to the second terminal 212 of the transistor(s) 200 through the metal layers 216.

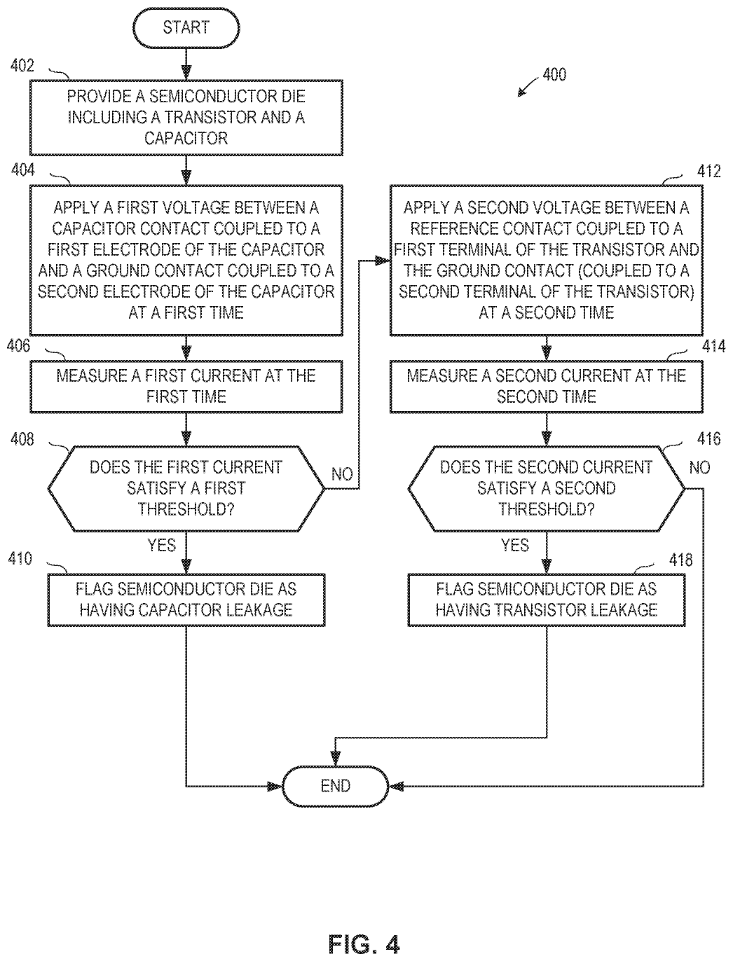

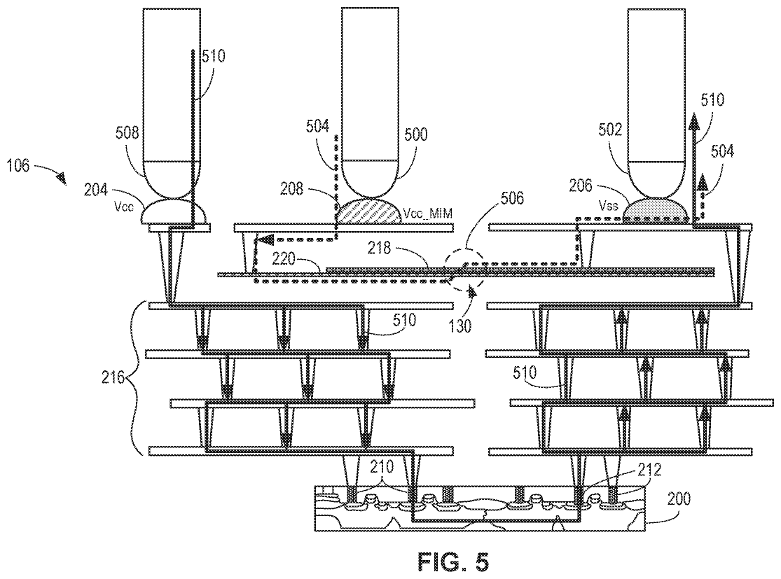

FIG. 4 is a flowchart representative of an example method 400 that may be performed through a testing process to detect defects (e.g., capacitor leakage, transistor leakage, etc.) associated with the semiconductor die 106 of FIGS. 2A, 2B, and 3. In some examples, some or all of the operations outlined in the example method of FIG. 4 are performed automatically by testing equipment that is programmed to perform the operations. Although the example method of testing is described with reference to the flowchart illustrated in FIG. 4, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example. The example method 400 begins at block 402, at which an example semiconductor die is provided, the example semiconductor die including an example transistor and an example capacitor. As shown in FIG. 5, the example semiconductor die 106 is provided including the transistor(s) 200 and the capacitor 130. In this example, the semiconductor die 106 includes separate bumps or contacts to supply voltage to the transistor(s) 200 (e.g., transistor supply contacts, voltage common collector (Vcc) contacts, the Vcc bump(s), etc.) and to the capacitor 130 (e.g., capacitor contacts, the Vcc_MIM bump(s), etc.). However, in this example, the same bumps or contacts (e.g., the Vss bump(s)) can electrically ground both the transistor(s) 200 and the capacitor 130.

At block 404, a first voltage is applied between an example capacitor contact coupled to a first electrode of the capacitor and a ground contact coupled to a second electrode of the capacitor at a first time. As shown in FIG. 5, a first voltage is applied between the third contact (e.g., the capacitor contact) 208 coupled to the electrode 220 of the capacitor 130 and the second contact (e.g., the ground contact) 206 coupled to the electrode 218 of the capacitor 130. In this example, the first voltage is applied by first and second example pins (e.g., pogo pins, spring mounted pogo pins, etc.) 500, 502 of a probe (e.g., test probe). The first example pin 500 is in physical contact with the third contact 208 and the second pin 502 is in physical contact with the second contact 206. In some examples, the first voltage may be approximately 0.8 Volts (V) (e.g., within 0.2 V).

At block 406, a first current is measured at the first time. In the example of FIG. 5, a first example current (represented by the arrows 504) flows across the capacitor 130 from the third contact 208 to the second electrode 220, to the first electrode 218, and to the second contact 206. For current to flow across a capacitor indicates there is leakage. That is, assuming there is no leakage, there would be no current. In such situations, the first current measured at block 406 would be zero (or near zero).

At block 408, it is determined whether the first current satisfies (e.g., exceeds) a first example threshold. In some examples, the first threshold is zero. In other examples, the first threshold may be slightly above zero. If the first current measurement (block 406) satisfies (e.g., exceeds) the first example threshold, this is an indication that there is a leak across the capacitor 130. Accordingly, in such examples, the process proceeds to block 410. Alternatively, if the first current measurement (block 406) does not satisfy (e.g., does not meet or exceed) the first threshold, this is an indication that there is no detectable leak in the capacitor 130. Accordingly, in such examples, the process proceeds to block 412.

At block 410, the example semiconductor die 106 is flagged as having capacitor leakage. That the first current 504 was able to cross the capacitor 130 is an indication that the capacitor 130 is associated with capacitor leakage. For purposes of illustration, the capacitor leakage is represented at an example location 506 on the capacitor 130. However, in other examples, the location of the leakage can be at any other location between the electrodes 218, 220 of the capacitor 130. Further, there may be multiple defects corresponding to multiple locations giving rise to leakage. In some examples, capacitor leakage may indicate that the capacitor 130 is defective (e.g., may fail). In some examples, the process ends after the semiconductor die 106 has been flagged (block 410) because the semiconductor die 106 is to be rejected such that further analysis or testing is unnecessary. Alternatively, to determine whether the semiconductor die has transistor leakage, the process may proceed to block 412.

At block 412, a second example voltage is applied between a transistor supply contact coupled to a first terminal of the transistor and the ground contact coupled to a second terminal of the transistor at a second time. That is the same ground contact is involved when applying the first voltage (at block 404) as when the second voltage is applied (at block 412). As shown in FIG. 5, a second voltage is applied between to the first example contact (e.g., the transistor supply contact) 204 coupled to the first terminal 210 of the transistor(s) 200 and the second contact (e.g., the ground contact) 206 coupled to the second terminal 212 of the transistor(s) 200. In this example, the second voltage is applied by a third example pin 508 of the probe and the second pin 502. The third example pin 508 is in physical contact with the first contact 204. In some examples, the second voltage may be approximately 0.8 V. Further, the second voltage and the first voltage may correspond to a same supply voltage.

At block 414, a second current is measured at the second time. As shown in FIG. 5, a second example current (represented by arrows 510) flows across the transistor 200 from the first contact 204, through the surfaces 216 to the first terminal 210, to the second terminal 212, and through the surfaces 216 to the second contact 206.

At block 416, it is determined whether the second current satisfies (e.g., exceeds) a second example threshold. In some examples, the second threshold is zero. In other examples, the second threshold is above zero. In some such examples, the second threshold is greater than the first threshold. If the second current measurement (block 414) satisfies (e.g., exceeds) the second example threshold, this is an indication that there is leakage across the transistor(s) 200. Accordingly, in such examples, the process proceeds to block 418. Alternatively, if the second current measurement (block 414) does not satisfy (e.g., does not meet or exceed) the second threshold, this is an indication that there is no detectable leak across the transistor(s) 200. Accordingly, in such examples, the process ends.

At block 418, the example semiconductor die 106 is flagged as having transistor leakage. That the second current 510 was able to cross the transistor(s) 200 is an indication that the transistor(s) 200 is associated with transistor leakage. There may be multiple defects corresponding to multiple locations in the transistor(s) 200 (e.g., between the terminals 210, 212) giving rise to leakage. In some examples, transistor leakage may indicate that the transistor is defective. Then, the process ends.

The leakage associated with the capacitor 130 may be determined independent (e.g., exclusive) of the leakage associated with the transistor 200. However, the second example pin 502 of the probe can measure the sum of the capacitor leakage and the transistor leakage. The sum of the capacitor leakage and the transistor leakage may be based on the first current measurement (block 406) and the second current measurement (block 414). Then, the process ends.

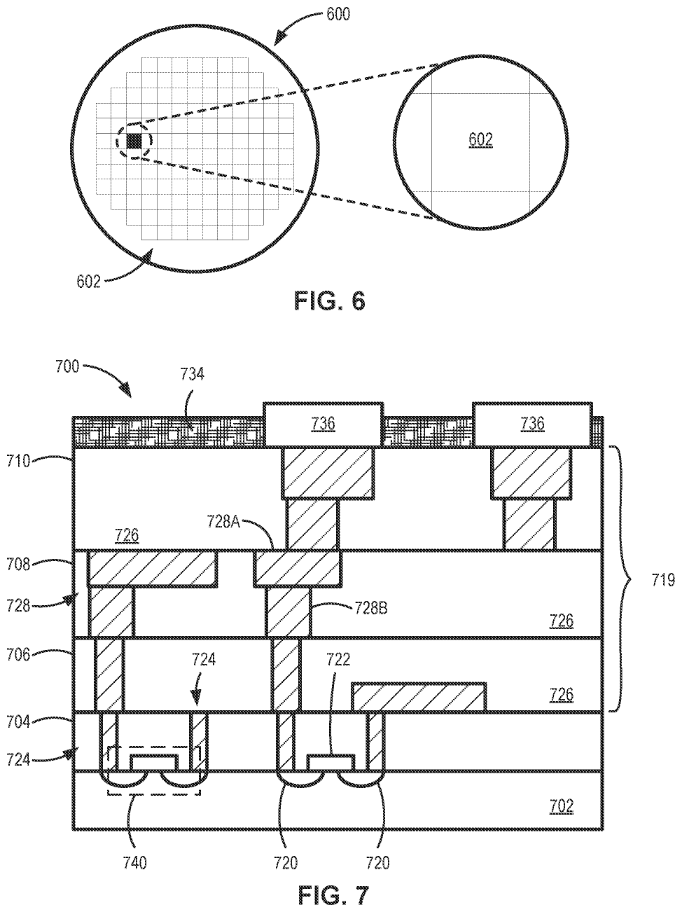

The example IC packages 100, 300 disclosed herein may be included in any suitable electronic component. FIGS. 6-9 illustrate various examples of apparatus that may include or be included in the IC packages 100, 300 disclosed herein.

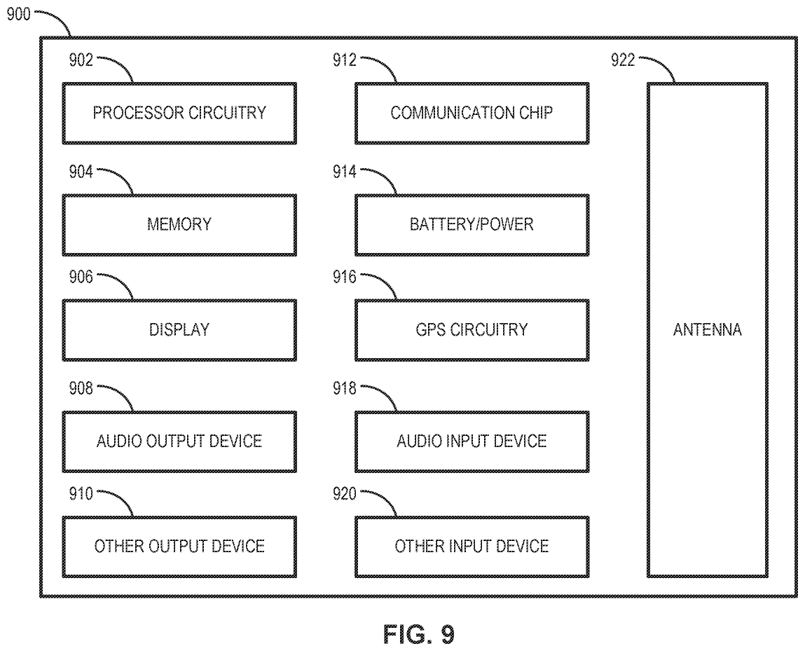

FIG. 6 is a top view of an example wafer 600 and dies 602 that may be included in the IC packages 100, 300 (e.g., as any suitable ones of the dies 106, 108 including the capacitor 130). The wafer 600 may be composed of semiconductor material and may include one or more dies 602 having circuitry. Some or all of the dies 602 may be a repeating unit of a semiconductor product. After the fabrication of the semiconductor product is complete, the wafer 600 may undergo a singulation process in which the dies 602 are separated from one another to provide discrete “chips.” The die 602 may include one or more transistors (e.g., some of the transistors 740 of FIG. 7, discussed below), supporting circuitry to route electrical signals to the transistors, passive components (e.g., traces, resistors, capacitors, inductors, and/or other circuitry), and/or any other components. In some examples, the die 602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 602. For example, a memory array formed by multiple memory circuits may be formed on a same die 602 as programmable circuitry (e.g., the processor circuitry 902 of FIG. 9) or other logic circuitry. Such memory may store information for use by the programmable circuitry. The example IC packages 100, 300 disclosed herein may be manufactured using a die-to-wafer assembly technique in which some dies 106, 108 are attached to a wafer 600 that include others of the dies 106, 108, and the wafer 600 is subsequently singulated.

FIG. 7 is a cross-sectional side view of an example IC device 700 that may be included in the example IC packages 100, 300 (e.g., in any one of the dies 106, 108). One or more of the IC devices 700 may be included in one or more dies 602 (FIG. 6). The IC device 700 may be formed on an example die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some examples, the die substrate 702 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an IC device 700 may be used. The die substrate 702 may be part of a singulated die (e.g., the dies 602 of FIG. 6) or a wafer (e.g., the wafer 600 of FIG. 6).

The IC device 700 may include one or more example device layers 704 disposed on or above the die substrate 702. The device layer 704 may include features of one or more example transistors 740 (e.g., metal oxide semiconductor field-effect transistors (MOSFETs)) formed on the die substrate 702. The device layer 704 may include, for example, one or more example source and/or drain (S/D) regions 720, an example gate 722 to control current flow between the S/D regions 720, and one or more example S/D contacts 724 to route electrical signals to/from the S/D regions 720. The transistors 740 may include additional features not depicted for the sake of clarity such as, for example, device isolation regions, gate contacts, and the like. The transistors 740 are not limited to the type and configuration depicted in FIG. 7 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 740 may include an example gate 722 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as for example a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 740 along the source-channel-drain direction, the gate electrode may include a U-shaped structure that includes a bottom portion substantially parallel to the surface of the die substrate 702 and two sidewall portions that are substantially perpendicular to the top surface of the die substrate 702. In other examples, at least one of the metal layers that form the gate electrode may be a planar layer that is substantially parallel to the top surface of the die substrate 702 and does not include sidewall portions substantially perpendicular to the top surface of the die substrate 702. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of respective ones of the transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes the dopants to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 720 may be formed using one or more alternate semiconductor materials such as germanium or a group III-V material or alloy. In further examples, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more example interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with example interconnect structures 728 of the interconnect layers 706-710. The one or more interconnect layers 706-710 may form an example metallization stack (also referred to as an “ILD stack”) 719 of the IC device 700.

The interconnect structures 728 may be arranged within the interconnect layers 706-710 to route electrical signals according to a wide variety of designs (in particular, the arrangement is not limited to the particular configuration of interconnect structures 728 depicted in FIG. 7). Although a particular number of interconnect layers 706-710 is depicted in FIG. 7, examples of the present disclosure include IC devices having more or fewer interconnect layers than depicted.

In some examples, the interconnect structures 728 may include example lines 728a and/or example vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page from the perspective of FIG. 7. The vias 728b may be arranged to route electrical signals in a direction of a plane that is substantially perpendicular to the surface of the die substrate 702 upon which the device layer 704 is formed. In some examples, the vias 728b may electrically couple lines 728a of different interconnect layers 706-710 together.

The interconnect layers 706-710 may include an example dielectric material 726 disposed between the interconnect structures 728, as shown in FIG. 7. In some examples, the dielectric material 726 disposed between the interconnect structures 728 in different ones of the interconnect layers 706-710 may have different compositions. In other examples, the composition of the dielectric material 726 between different interconnect layers 706-710 may be the same.

A first interconnect layer 706 (referred to as Metal 1 or “M1”) may be formed directly on the device layer 704. In some examples, the first interconnect layer 706 may include lines 728a and/or vias 728b, as shown. The lines 728a of the first interconnect layer 706 may be coupled with contacts (e.g., the S/D contacts 724) of the device layer 704.

A second interconnect layer 708 (referred to as Metal 2 or “M2”) may be formed directly on the first interconnect layer 706. In some examples, the second interconnect layer 708 may include vias 728b to couple the lines 728a of the second interconnect layer 708 with the lines 728a of the first interconnect layer 706. Although the lines 728a and the vias 728b are structurally delineated with a line within each interconnect layer (e.g., within the second interconnect layer 708) for the sake of clarity, the lines 728a and the vias 728b may be structurally and/or materially contiguous (e.g., simultaneously filled during a dual-damascene process) in some examples.

A third interconnect layer 710 (referred to as Metal 3 or “M3”) (and additional interconnect layers, as desired) may be formed in succession on the second interconnect layer 708 according to similar techniques and configurations described in connection with the second interconnect layer 708 and/or the first interconnect layer 706. In some examples, the interconnect layers that are “higher up” in the metallization stack 719 in the IC device 700 (i.e., further away from the device layer 704) may be thicker.

The IC device 700 may include an example solder resist material 734 (e.g., polyimide or similar material) and one or more example conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to other external devices. For example, solder bonds may be formed on the one or more conductive contacts 736 to mechanically and/or electrically couple a chip including the IC device 700 with another component (e.g., a circuit board). The IC device 700 may include additional or alternate structures to route the electrical signals from the interconnect layers 706-710; for example, the conductive contacts 736 may include other analogous features (e.g., posts) that route the electrical signals to external components.

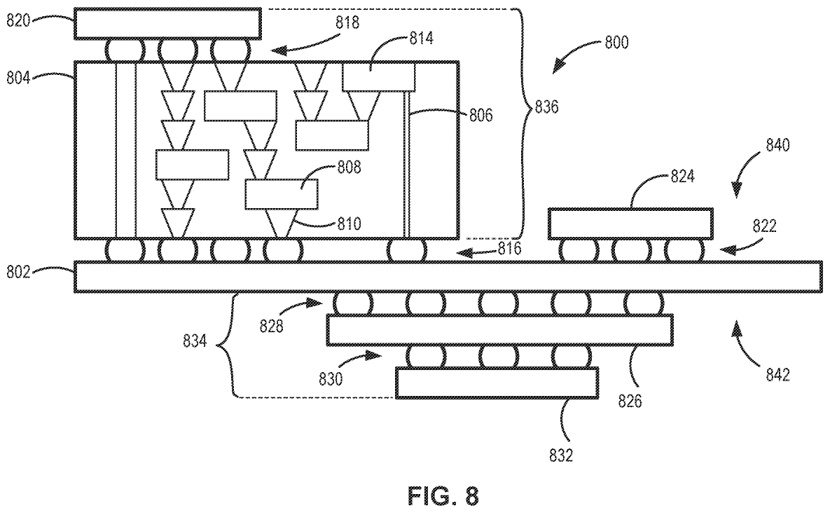

FIG. 8 is a cross-sectional side view of an example IC device assembly 800 that may include the IC packages 100, 300 disclosed herein. In some examples, the IC device assembly corresponds to the IC packages 100, 300. The IC device assembly 800 includes a number of components disposed on an example circuit board 802 (which may be, for example, a motherboard). The IC device assembly 800 includes components disposed on an example first face 840 of the circuit board 802 and an example opposing second face 842 of the circuit board 802. Any of the IC packages discussed herein with reference to the IC device assembly 800 may take the form of the example IC packages 100, 300.

In some examples, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other examples, the circuit board 802 may be a non-PCB substrate. In some examples, the circuit board 802 may be, for example, the circuit board 102 of FIG. 1.

The IC device assembly 800 illustrated in FIG. 8 includes an example package-on-interposer structure 836 coupled to the first face 840 of the circuit board 802 by example coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical, chemical, and/or mechanical coupling structure.

The package-on-interposer structure 836 may include an example IC package 820 coupled to an example interposer 804 by example coupling components 818. The coupling components 818 may take any suitable form for the application, such as the forms discussed above with reference to the coupling components 816. Although a single IC package 820 is shown in FIG. 8, multiple IC packages may be coupled to the interposer 804. Additionally or alternatively, in some examples, additional interposers may be coupled to the interposer 804. The interposer 804 may provide an intervening substrate used to bridge the circuit board 802 and the IC package 820. The IC package 820 may be or include, for example, a die (the die 602 of FIG. 6), an IC device (e.g., the IC device 700 of FIG. 7), and/or any other suitable component(s). Generally, the interposer 804 may spread a connection to a wider pitch or reroute a connection to a different connection. For example, the interposer 804 may couple the IC package 820 (e.g., a die) to a set of BGA conductive contacts of the coupling components 816 for coupling to the circuit board 802. In the example illustrated in FIG. 8, the IC package 820 and the circuit board 802 are attached to opposing sides of the interposer 804. In other examples, the IC package 820 and the circuit board 802 may be attached to a same side of the interposer 804. In some examples, three or more components may be interconnected by way of the interposer 804.

In some examples, the interposer 804 may be formed as a PCB, including multiple metal layers separated from one another by layers of dielectric material and interconnected by electrically conductive vias. In some examples, the interposer 804 may be formed of an epoxy resin, a fiberglass-reinforced epoxy resin, an epoxy resin with inorganic fillers, a ceramic material, or a polymer material such as polyimide. In some examples, the interposer 804 may be formed of alternate rigid or flexible materials that may include the same materials described above for use in a semiconductor substrate, such as silicon, germanium, and other group III-V and group IV materials. The interposer 804 may include example metal interconnects 808 and example vias 810, including but not limited to example through-silicon vias (TSVs) 806. The interposer 804 may further include example embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an example IC package 824 coupled to the first face 840 of the circuit board 802 by example coupling components 822. The coupling components 822 may take the form of any of the examples discussed above with reference to the coupling components 816, and the IC package 824 may take the form of any of the examples discussed above with reference to the IC package 820.

The IC device assembly 800 illustrated in FIG. 8 includes an example package-on-package structure 834 coupled to the second face 842 of the circuit board 802 by coupling components 828. The package-on-package structure 834 may include a first example IC package 826 and a second example IC package 832 coupled together by example coupling components 830 such that the first IC package 826 is disposed between the circuit board 802 and the second IC package 832. The coupling components 828, 830 may take the form of any of the examples of the coupling components 816 discussed above, and the IC packages 826, 832 may take the form of any of the examples of the IC package 820 discussed above.

FIG. 9 is a block diagram of an example electrical device 900 that may include one or more of the example IC packages 100, 300. For example, any suitable ones of the components of the electrical device 900 may include one or more of the device assemblies 800, IC devices 700, or dies 602 disclosed herein, and may be arranged in the example IC packages 100, 300. A number of components are illustrated in FIG. 9 as included in the electrical device 900, but any one or more of these components may be omitted or duplicated, as suitable for the application. In some examples, some or all of the components included in the electrical device 900 may be attached to one or more motherboards. In some examples, some or all of these components are fabricated onto a single system-on-a-chip (SoC) die.

Additionally, in some examples, the electrical device 900 may not include one or more of the components illustrated in FIG. 9, but the electrical device 900 may include interface circuitry for coupling to the one or more components. For example, the electrical device 900 may not include an example display 906, but may include display interface circuitry (e.g., a connector and driver circuitry) to which the display 906 may be coupled. In some examples, the electrical device 900 may not include an example audio input device 918 (e.g., microphone) or an example audio output device 908 (e.g., a speaker, a headset, earbuds, etc.), but may include audio input or output device interface circuitry (e.g., connectors and supporting circuitry) to which the audio input device 918 or the audio output device 908 may be coupled.

The electrical device 900 may include example programmable or processor circuitry 902 (e.g., one or more processing devices). The processor circuitry 902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 900 may include an example memory 904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 904 may include memory that shares a die with the processor circuitry 902. This memory may be used as cache memory and may include embedded dynamic random access memory (eDRAM) or spin transfer torque magnetic random access memory (STT-MRAM).

In some examples, the electrical device 900 may include an example communication chip 912 (e.g., one or more communication chips). For example, the communication chip 912 may be configured for managing wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other examples. The electrical device 900 may include an example antenna 922 to facilitate wireless communications and/or to receive other wireless communications (such as AM or FM radio transmissions).

In some examples, the communication chip 912 may manage wired communications, such as electrical, optical, or any other suitable communication protocols (e.g., the Ethernet). As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as global positioning system (GPS), EDGE, GPRS, CDMA, WiMAX, LTE, EV-DO, or others. In some examples, a first communication chip 912 may be dedicated to wireless communications, and a second communication chip 912 may be dedicated to wired communications.

The electrical device 900 may include example battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include the display 906 (or corresponding interface circuitry, as discussed above). The display 906 may include any visual indicators, such as a heads-up display, a computer monitor, a projector, a touchscreen display, a liquid crystal display (LCD), a light-emitting diode display, or a flat panel display.

The electrical device 900 may include the audio output device 908 (or corresponding interface circuitry, as discussed above). The audio output device 908 may include any device that generates an audible indicator, such as speakers, headsets, or earbuds.

The electrical device 900 may include the audio input device 918 (or corresponding interface circuitry, as discussed above). The audio input device 918 may include any device that generates a signal representative of a sound, such as microphones, microphone arrays, or digital instruments (e.g., instruments having a musical instrument digital interface (MIDI) output).

The electrical device 900 may include example GPS circuitry 916. The GPS circuitry 916 may be in communication with a satellite-based system and may receive a location of the electrical device 900, as known in the art.

The electrical device 900 may include any other example output device 910 (or corresponding interface circuitry, as discussed above). Examples of the other output device 910 may include an audio codec, a video codec, a printer, a wired or wireless transmitter for providing information to other devices, and/or an additional storage device.

The electrical device 900 may include any other example input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 900 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the usage of capacitors included in semiconductor dies. For example, disclosed examples provide effective detection methods to identify defective capacitors in an example semiconductor die (e.g., the die 106). Examples disclosed herein distinguish between transistor leakage (associated with the semiconductor die as a whole) and capacitor leakage (associated with a capacitor included in the semiconductor die). For example, disclosed examples define a first current path to measure transistor leakage and a second current path to measure capacitor leakage. Disclosed examples short (e.g., reroute) the second current path so that current passes through the capacitor exclusively, rather than through the die in its entirety. In some disclosed examples, measuring capacitor leakage by supplying a voltage to the example semiconductor die can also identify capacitor defects associated with changes in temperature (since temperature varies as voltage varies). In some disclosed examples, measurements across the first current path and/or the second current path may be obtained with wafer sorting test methods, wafer-level-burn-in techniques, etc., during assembly of the example semiconductor die. Therefore, disclosed examples may detect capacitor leakage prior to fabricating the IC package and/or prior to sending the assembled IC package into the field. Additionally, disclosed examples may detect capacitor leakage in IC packages that have been returned from the field.

Example 1 includes a semiconductor die comprising a transistor, a first contact on a first surface of the semiconductor die, the first contact electrically coupled to a first terminal of the transistor, a second contact on the first surface of the semiconductor die, the second contact electrically coupled to a second terminal of the transistor, a capacitor between the first surface and a second surface of the semiconductor die opposite the first surface, the second contact electrically coupled to a first electrode of the capacitor, and a third contact on the first surface of the semiconductor die, the third contact electrically coupled to a second electrode of the capacitor.

Example 2 includes the semiconductor die of example 1, further including a first conductive via extending from the first electrode to the first surface and a second conductive via extending from the second electrode to the first surface.

Example 3 includes the semiconductor die of example 1, wherein the first terminal is a drain terminal of the transistor and the second terminal is a source terminal of the transistor.

Example 4 includes the semiconductor die of example 1, wherein the first and third contacts are voltage common collector (VCC) contacts and the second contact is a ground contact.

Example 5 includes the semiconductor die of example 1, wherein the third contact is one of a set of multiple contacts distributed across the first surface, different contacts in the set of multiple contacts electrically coupled to the second electrode of the capacitor.

Example 6 includes the semiconductor die of example 1, wherein the third contact is positioned between and spaced apart from the first and second contacts.

Example 7 includes the semiconductor die of example 1, wherein the first, second, third contacts are electrically couplable with a package substrate.

Example 8 includes the semiconductor die of example 7, wherein the package substrate is electrically coupled to the first electrode via the second contact and to the second electrode via the third contact.

Example 9 includes the semiconductor die of example 1, wherein the first, second, and third contacts are associated with respective first, second and third portions of a metal layer adjacent the first surface of the semiconductor die, the first portion of the metal layer spaced apart from the second portion of the metal layer and spaced apart from the third portion of the metal layer, the second portion of the metal layer spaced apart from the third portion of the metal layer.

Example 10 includes the semiconductor die of example 9, wherein the first and second electrodes extend in planes substantially parallel to the first surface, both the second and third portions of the metal layer overlap with the first and second electrodes in a direction substantially perpendicular to the first surface.

Example 11 includes an integrated circuit (IC) package comprising a package substrate, and a semiconductor die including a metal layer, bumps to interconnect with the package substrate, different ones of the bumps positioned on different segments of the metal layer, a transistor including a drain electrically coupled to a first one of the bumps, and including a source electrically coupled to a second one of the bumps, and a capacitor capacitively coupling a third one of the bumps to the second bump, the third bump closer to the second bump than the first bump is to the second bump.

Example 12 includes the IC package of example 11, wherein the first bump is electrically isolated from the third bump within the semiconductor die, the first bump electrically coupled to the third bump through the package substrate.

Example 13 includes the IC package of example 11, wherein the first bump is positioned on a first one of the segments, the second bump is positioned on a second one of the segments, and the third bump is positioned on a third one of the segments, the first, second, and third segments spaced apart from one another.

Example 14 includes the IC package of example 13, wherein the capacitor includes a first electrode and a second electrode, the first electrode closer to the transistor than the second electrode is to the transistor.

Example 15 includes the IC package of example 14, wherein the first electrode extends a first length along a first axis, the third segment extends a second length along the first axis less than the first length, the first electrode extends beyond both ends of the second length of the third segment along the first axis.

Example 16 includes the IC package of example 14, wherein the package substrate is electrically coupled to the first electrode via the third bump and to the second electrode via the second bump.

Example 17 includes the IC package of example 14, wherein the capacitor is a thin film metal-insulator-metal (MIM) capacitor.

Example 18 includes a method comprising providing a semiconductor die including a transistor and a capacitor, the semiconductor die having a first contact electrically coupled to a first terminal of the transistor, a second contact electrically coupled to a second terminal of the transistor and to a first electrode of the capacitor, and a third contact electrically coupled to a second electrode of the capacitor, providing a first voltage to the third contact via a first pin of a probe contacting the third contact, providing a ground source via a second pin of the probe contacting the second contact, and determining a first leakage associated with the capacitor based on a first current measured when the first voltage is provided to the third contact, the first leakage determined independent of a second leakage associated with the transistor.

Example 19 includes the method of example 18, wherein the providing of the first voltage is provided at a first time, the method further including providing, at a second time, a second voltage to the first contact via a third pin of the probe contacting the first contact, and determining the second leakage based on a second current measured at the second time.

Example 20 includes the method of example 19, wherein the first voltage and the second voltage correspond to a same supply voltage.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A semiconductor die comprising:
a transistor;
a first contact on a first surface of the semiconductor die, the first contact electrically coupled to a first terminal of the transistor;
a second contact on the first surface of the semiconductor die, the second contact electrically coupled to a second terminal of the transistor;
a capacitor between the first surface and a second surface of the semiconductor die opposite the first surface, the second contact electrically coupled to a first electrode of the capacitor; and
a third contact on the first surface of the semiconductor die, the third contact electrically coupled to a second electrode of the capacitor.

2. The semiconductor die of claim 1, further including a first conductive via extending from the first electrode to the first surface and a second conductive via extending from the second electrode to the first surface.

3. The semiconductor die of claim 1, wherein the first terminal is a drain terminal of the transistor and the second terminal is a source terminal of the transistor.

4. The semiconductor die of claim 1, wherein the first and third contacts are voltage common collector (VCC) contacts and the second contact is a ground contact.

5. The semiconductor die of claim 1, wherein the third contact is one of a set of multiple contacts distributed across the first surface, different contacts in the set of multiple contacts electrically coupled to the second electrode of the capacitor.

6. The semiconductor die of claim 1, wherein the third contact is positioned between and spaced apart from the first and second contacts.

7. The semiconductor die of claim 1, wherein the first, second, third contacts are electrically couplable with a package substrate.

8. The semiconductor die of claim 7, wherein the package substrate is electrically coupled to the first electrode via the second contact and to the second electrode via the third contact.

9. The semiconductor die of claim 1, wherein the first, second, and third contacts are associated with respective first, second and third portions of a metal layer adjacent the first surface of the semiconductor die, the first portion of the metal layer spaced apart from the second portion of the metal layer and spaced apart from the third portion of the metal layer, the second portion of the metal layer spaced apart from the third portion of the metal layer.

10. The semiconductor die of claim 9, wherein the first and second electrodes extend in planes substantially parallel to the first surface, both the second and third portions of the metal layer overlap with the first and second electrodes in a direction substantially perpendicular to the first surface.

11. An integrated circuit (IC) package comprising:
a package substrate; and
a semiconductor die including:
a metal layer;
bumps to interconnect with the package substrate, different ones of the bumps positioned on different segments of the metal layer;
a transistor including a drain electrically coupled to a first one of the bumps, and including a source electrically coupled to a second one of the bumps; and
a capacitor capacitively coupling a third one of the bumps to the second bump, the third bump closer to the second bump than the first bump is to the second bump.

12. The IC package of claim 11, wherein the first bump is electrically isolated from the third bump within the semiconductor die, the first bump electrically coupled to the third bump through the package substrate.

13. The IC package of claim 11, wherein the first bump is positioned on a first one of the segments, the second bump is positioned on a second one of the segments, and the third bump is positioned on a third one of the segments, the first, second, and third segments spaced apart from one another.

14. The IC package of claim 13, wherein the capacitor includes a first electrode and a second electrode, the first electrode closer to the transistor than the second electrode is to the transistor.

15. The IC package of claim 14, wherein the first electrode extends a first length along a first axis, the third segment extends a second length along the first axis less than the first length, the first electrode extends beyond both ends of the second length of the third segment along the first axis.

16. The IC package of claim 14, wherein the package substrate is electrically coupled to the first electrode via the third bump and to the second electrode via the second bump.

17. The IC package of claim 14, wherein the capacitor is a thin film metal-insulator-metal (MIM) capacitor.

18. A method comprising:
providing a semiconductor die including a transistor and a capacitor, the semiconductor die having a first contact electrically coupled to a first terminal of the transistor, a second contact electrically coupled to a second terminal of the transistor and to a first electrode of the capacitor, and a third contact electrically coupled to a second electrode of the capacitor;
providing a first voltage to the third contact via a first pin of a probe contacting the third contact;
providing a ground source via a second pin of the probe contacting the second contact; and
determining a first leakage associated with the capacitor based on a first current measured when the first voltage is provided to the third contact, the first leakage determined independent of a second leakage associated with the transistor.

19. The method of claim 18, wherein the providing of the first voltage is provided at a first time, the method further including:
providing, at a second time, a second voltage to the first contact via a third pin of the probe contacting the first contact; and
determining the second leakage based on a second current measured at the second time.

20. The method of claim 19, wherein the first voltage and the second voltage correspond to a same supply voltage.
